(19) United States
(12) Patent Application Publication
(10) Pub. No.: US 2002/0137345 A1
(43) Pub. Date: Sep. 26, 2002

(54) Gate resistance reduction

(76) Inventors: Cheisan J. Yue, Roseville, MN (US); Eric E. Vogt, Minneapolis, MN (US)

Correspondence Address: HONEYWELL INTERNATIONAL INC., 101 COLUMBIA ROAD, P O BOX 2245, MORRISTOWN, NJ, 07962-2245, US

(21) Appl. No.: 09/757,948

(22) Filed: Jan. 10, 2001

(51) Int. Cl. H01L 29/76; H01L 29/94; H01L 31/062; H01L 31/113; H01L 31/119; H01L 21/3205; H01L 21/4763; H01L 21/311

(52) U.S. Cl. 438/694

(57) ABSTRACT

A transistor has a gate, a source, and a drain. A spacer around the gate is etched so as to expose a top wall and at least a portion of a sidewall of the gate. Silicide layers contact the top wall and the exposed portion of the sidewall of the gate, the source, and the drain of the transistor.

### TECHNICAL FIELD OF THE INVENTION

The present invention relates to the reduction of gate resistance in certain semiconductor devices such as MOS transistors.

### BACKGROUND OF THE INVENTION AND PRIOR ART

It is well known that gate resistance plays an important role in determining the maximum cut-off frequency (Fmax) and noise figure (NF) of such semiconductor devices as MOS transistors. Therefore, it is generally an objective of semiconductor fabrication techniques for certain applications, especially those involving transistor fabrication, to reduce gate resistance.

One known way of reducing gate sheet resistance and, therefore, gate resistance is by the use of a silicidation process. Gate resistance R_{G} is related to gate sheet resistance R_{GS} by the following equation:

$${R}_{G} = {R}_{G S} ( \frac{1}{w} )$$

where l and w are the length and width of the gate. A conventional silicidation process is illustrated in FIGS. 1 and 2. As shown in FIG. 1, a spacer 10 is provided around a gate 12 of a semiconductor device 14 that is being fabricated. The height of the spacer 10 is commensurate with the width w of the gate 12. The semiconductor device 14 has a substrate 16 and, as is usual in fabricating an MOS transistor, a source 18 and a drain 20 are formed in the substrate 16. During silicidation, silicide layers 22, 24, and 26 are formed over the gate 12, the source 18, and the drain 20, respectively.

Lower gate sheet resistance can also be achieved by properly selecting a refractory metal for silicidation. Moreover, thicker silicidation, in general, results in lower gate sheet resistance. However, the upper bound of silicidation thickness is often limited by the shallow source and drain depths, which are typically less than 100 nm for VLSI devices.

The present invention involves a unique technique which results in lower gate resistance than the conventional methods discussed above.

### SUMMARY OF THE INVENTION

In accordance with one aspect of the present invention, a method is provided to form a region of a semiconductor device. The region has a spacer therearound. The method comprises etching the spacer so as to expose a top wall and at least a portion of a sidewall of the region, and siliciding the top wall and the exposed portion of the sidewall of the region.

In accordance with another aspect of the present invention, a method is provided to form a gate of a transistor. The gate has a spacer therearound. The method comprises etching the spacer so as to expose a top wall and at least a portion of a sidewall of the gate, and siliciding the top wall and the exposed portion of the sidewall of the gate.

In accordance with still another aspect of the present invention, a transistor comprises a gate, a source, a drain, a spacer, and first, second, and third silicide layers. The spacer is around the gate and exposes a top wall and at least a portion of a sidewall of the gate. The first silicide layer contacts the top wall and the exposed portion of the sidewall of the gate. The second silicide layer contacts the source. The third silicide layer contacts the drain.

In accordance with yet another aspect of the present invention, a transistor comprises a gate, a source, a drain, and first, second, third, and fourth silicide layers. The gate has a top wall and a sidewall. The first silicide layer contacts the top wall of the gate. The second silicide layer contacts at least a portion of the sidewall of the gate. The third silicide layer contacts the source. The fourth silicide layer contacts the drain.

In accordance with a further aspect of the present invention, a semiconductor device comprises a region, a spacer, and a silicide layer. The spacer is around the region so as to expose a top wall and at least a portion of a sidewall of the region. The silicide layer is around the top wall and the exposed portion of the sidewall of the region.

### BRIEF DESCRIPTION OF THE DRAWINGS

These and other features and advantages will become more apparent from a detailed consideration of the invention when taken in conjunction with the drawings in which:

FIGS. 1 and 2 illustrate a conventional silicidation process used in fabricating a semiconductor device;

FIGS. 3, 4, and 5 illustrate a silicidation process according to the present invention; and,

FIG. 6 shows the silicidation of the gate that results in a device having essentially silicide for the gate.

### DETAILED DESCRIPTION

A silicidation process in accordance with an embodiment of the present invention is illustrated in FIGS. 3, 4, and 5. As is customary, a conventional spacer 30, such as a conventional deposited oxide, is provided around a gate 32 of a semiconductor device 34 that is being fabricated. Also as is customary, the height of the spacer 30 is initially commensurate with the width of the gate 32.

Using a conventional etchant, the spacer 10 is then over etched as shown in FIG. 4 so that the top of the gate 32 and a portion of the sidewall 36 of the gate 32 are exposed. The exposed portion of the sidewall 36 may or may not extend entirely around the sidewall 36 of the gate 32.

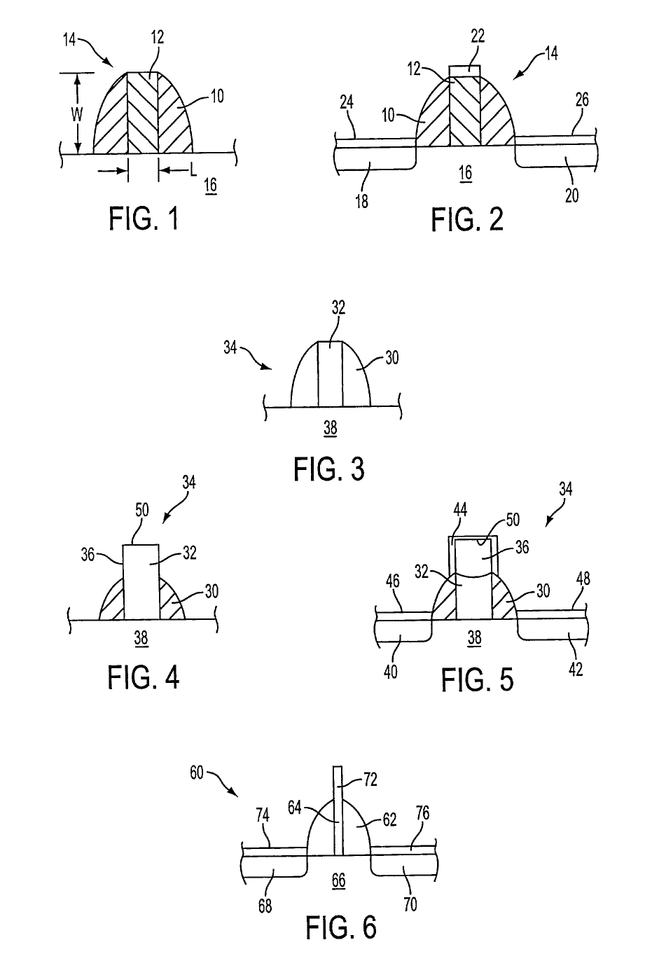

The semiconductor device 34 has a substrate 38 and, as is usual in fabricating an MOS transistor, a source 40 and a drain 42 are formed in the substrate 38. During silicidation, silicide layers 44, 46, and 48 are formed over the gate 32, the source 40, and the drain 42, respectively. However, unlike the semiconductor device 14 shown in FIGS. 1 and 2, the silicide layer 44 coats not only a top wall 50 of the gate 32, but also the exposed portion of the sidewall 36.

Thus, the silicidation process shown in FIGS. 3, 4, and 5 takes advantage of the three dimensional nature of the gate 32 of the semiconductor device 34, whereas the silicidation process shown in FIGS. 1 and 2 is only two dimensional. Accordingly, the silicidation process shown in FIGS. 3, 4, and 5 results in a lower gate sheet resistance and, therefore, a lower resistance than does the conventional silicidation process shown in FIGS. 1 and 2.

It is possible in deep micron devices for the gate to be so narrow that silicidation of the gate results in a device having essentially silicide for the gate. Such a device 60 is shown in FIG. 6. The device 60 has a spacer 62 and a gate 64. The gate 64 is essentially silicide. The device 60 has a substrate 66 in which a source 68 and a drain 70 are formed. During silicidation, silicide layers 72, 74, and 76 are formed over the gate 64, the source 68, and the drain 70, respectively. Unlike the semiconductor device 14 shown in FIGS. 1 and 2, the silicide layer 72 extends over the top and sides of the gate 64.

Certain modifications of the present invention have been discussed above. Other modifications will occur to those practicing in the art of the present invention. For example, for an extreme submicron device, a complete silicidation of the gate could be performed to further reduce gate resistance so that the silicide layer covering the sidewall of the gate extends from the top wall of the gate substantially to the substrate.

Also, an oxide is suggested above as a specific exemplary material that can be used for the spacer 30. However, any other suitable material, such as a nitride, can be used for the spacer 30.

Moreover, a transistor having a gate 12 is suggested above as a specific embodiment for the semiconductor device 14. However, the semiconductor device 14 can be other devices and the gate 12 can be other regions of such other devices requiring silicidation.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

What is claimed is:

1. A method of forming a region of a semiconductor device, wherein the region has a spacer therearound, and wherein the method comprises:
etching the spacer so as to expose a top wall and at least a portion of a sidewall of the region; and,
siliciding the top wall and the exposed portion of the sidewall of the region.

2. The method of claim 1 wherein the region is a gate, and wherein the silicidation of the top wall and the exposed portion of the sidewall of the region comprises:
forming a drain and a source in a substrate; and,
siliciding the gate, the source, and the drain so that the top wall of the gate, the exposed portion of the sidewall of the gate, the source, and the drain are covered with corresponding layers of silicide.

3. A method of forming a gate of a transistor, wherein the gate has a spacer therearound, and wherein the method comprises:
etching the spacer so as to expose a top wall and at least a portion of a sidewall of the gate; and,
siliciding the top wall and the exposed portion of the sidewall of the gate.

4. The method of claim 3 wherein the transistor further includes a source and a drain, and wherein the silicidation of the top wall and the exposed portion of the sidewall of the gate comprises siliciding the gate, the source, and the drain so that the top wall and the exposed portion of the sidewall of the gate, the source, and the drain are contacted with layers of silicide.

5. A transistor comprising:
a gate, a source, and a drain;
a spacer around the gate, wherein the spacer exposes a top wall and at least a portion of a sidewall of the gate;
a first silicide layer contacting the top wall and the exposed portion of the sidewall of the gate;
a second silicide layer contacting the source; and,
a third silicide layer contacting the drain.

6. A transistor comprising:
a gate having a top wall and a sidewall;
a source;
a drain;
a first silicide layer contacting the top wall of the gate;
a second silicide layer contacting at least a portion of the sidewall of the gate;
a third silicide layer contacting the source; and,
a fourth silicide layer contacting the drain.

7. The transistor of claim 6 wherein the first and second silicide layers comprise a single continuous silicide layer.

8. The transistor of claim 6 further comprising a substrate, wherein the gate extends from the substrate, wherein the source and the drain are formed in the substrate, and wherein the second silicide layer extends along the sidewall substantially from the top wall to the substrate.

9. The transistor of claim 8 wherein the first and second silicide layers comprise a single continuous layer.

10. A semiconductor device comprising:
a region;
a spacer around the region so as to expose a top wall and at least a portion of a sidewall of the region; and,
a silicide layer around the top wall and the exposed portion of the sidewall of the region.

11. The semiconductor device of claim 10 wherein the silicide layer comprises a first silicide layer covering the top wall of the region and a second silicide layer covering the exposed portion of the sidewall of the region.

12. The semiconductor device of claim 11 wherein the first and second silicide layers form a continuous silicide layer.

13. The semiconductor device of claim 10 wherein the region is a gate.

14. The semiconductor device of claim 10 wherein the region is a gate of a transistor.
